(19) United States
(12) Patent Application Publication
(10) Pub. No.: US 2024/0120375 A1
(43) Pub. Date: Apr. 11, 2024

(54) HIGH PERFORMANCE 3D CHANNELS WITH UPSILON NANOSHEETS

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/962,222

(22) Filed: Oct. 7, 2022

(51) Int. Cl. H01L 29/06; H01L 21/8238; H01L 29/66; H01L 29/775; H01L 29/786

(52) U.S. Cl. CPC H01L 29/0673; H01L 21/823807; H01L 29/66439; H01L 29/775; H01L 29/78696

(57) ABSTRACT

A method for fabricating and a structure comprising one or more transistors where a transistor includes one or more nanosheets formed based on one or more layers of a nanosheet material. A layer of shell material can at least partly surround the one or more nanosheets to form one or more channels of the transistor. A gate structure of the transistor can at least partly surround each of the one or more channels. The gate structure can include a gate dielectric disposed between the layer of the shell material and a gate metal of the gate structure for each of the nanosheets, where the shell material can include a charge carrier mobility that is greater than a charge carrier mobility of the nanosheet material.

### TECHNICAL FIELD

This disclosure related to microelectronic devices including semiconductor 3D devices and design as well as methods of fabrication.

### BACKGROUND

Fabrication of semiconductor devices relies on various fabrication processes that are performed repeatedly in order to form desired semiconductor features on a substrate. In the recent years, scaling down semiconductor devices became more challenging as features sizes reached single digit nanometer range.

### SUMMARY

To continue scaling semiconductor devices having features single digit nanometer feature sizes while improving their performance, the semiconductor devices can be designed vertically with respect to the surface of the substrate. Such vertically oriented devices can be referred to as three-dimensional (3D) semiconductor devices and can include transistor structures that are stacked vertically (e.g., one on top of one another), thereby allowing for greater device density per surface area. Fabricating 3D semiconductor devices efficiently, however, can be difficult for various types of architectures, such as those involving nanosheet-based NMOS and PMOS transistors.

The present solution provides 3D nanosheet NMOS and PMOS transistor structures and fabrication processes for efficiently fabricating thereof. The present solution can utilize one epitaxially grown materials (e.g., silicon germanium, or SiGe) to form one or more nanosheets for a transistor with one or more transistor channels. The present solution can utilize another one or more epitaxially grown materials, such as Ge or SiGe, having improved charge mobility characteristics in order to provide one or more shell layers between the nanosheet and the gate structure to improve the performance of the transistor.

The present solution can enable an improved circuit density using a compact upsilon nanosheet design, which can include a compact nanosheet design and u-shaped nanosheets. The present disclosure can include shells that can be epitaxially grown on nanosheets used to form channels of vertical transistor structures to improve the performance of the transistor structures that include NMOS and PMOS transistors. 3D isolations can provide electrical isolation of adjacent 3D stacked transistors as well as edge isolation inserts that include selective dielectrics allowing transistors (e.g., NMOS and PMOS) to have separate channel release and different high-k and gate metal materials for improved performance across the NMOS and PMOS structure. The present solution can reduce the number of process steps to achieve the desired structure and allow for N stack tall structures, as well as side by side transistor structures. The present solution can use 3D stacked differential gate metals for high performance NMOS and PMOS device structure and selective dielectric to allow top access without using a masking layer.

In some aspects, the present disclosure relates to a structure. The structure can include a transistor. The transistor can include a nanosheet formed based on a layer of a nanosheet material. The transistor can include a layer of a shell material at least partly surrounding the nanosheet to form a channel. The transistor can include a gate structure. The gate structure can at least partly surrounding the channel. The gate structure can include a gate dielectric disposed between the layer of the shell material and a gate metal of the gate structure. The shell material can include a charge carrier mobility that is greater than a charge carrier mobility of the nanosheet material.

The structure can include the transistor that is a p-type metal oxide semiconductor (PMOS) transistor. The layer of a nanosheet material in the PMOS transistor can be oriented horizontally. The PMOS transistor can include a second nanosheet formed based on a second layer of the nanosheet material. The second layer can be oriented horizontally and disposed beneath the layer of the nanosheet material. The PMOS transistor can include a third nanosheet formed based on a third layer of the nanosheet material. The third layer can be oriented horizontally and disposed beneath the second layer of the nanosheet material. The PMOS transistor can include a second layer of the shell material at least partly surrounding the second nanosheet to form a second channel. The PMOS transistor can include a third layer of the shell material at least partly surrounding the third nanosheet to form a third channel. The PMOS transistor can include the gate structure at least partly surrounding the second channel and at least partly surrounding the third channel. The gate dielectric can be disposed between the gate metal and the second layer of the shell material and between the gate metal and the third layer of the shell material.

The structure can include the PMOS transistor disposed beside an n-type metal oxide semiconductor (NMOS) transistor. The NMOS transistor can include a fourth nanosheet to form a fourth channel. The fourth nanosheet can be formed based on the layer of the nanosheet material. The NMOS transistor can include a fifth nanosheet to form a fifth channel. The fifth nanosheet formed based on the second layer of the nanosheet material. The NMOS transistor can include a sixth nanosheet to form a sixth channel. The sixth nanosheet can be formed based on the third layer of the nanosheet material. The NMOS transistor can include a second gate structure at least partly surrounding each of the fourth channel, the fifth channel, and the sixth channel. The second gate structure can include a second gate dielectric disposed between a second gate metal of the second gate structure and the fourth nanosheet, between the second gate metal and the fifth nanosheet and between the second gate metal and the sixth nanosheet.

The structure can include an isolation trench oriented vertically and disposed between the gate structure of the PMOS transistor and the second gate structure of the NMOS transistor. The isolation trench can electrically isolate the gate structure and the second gate structure. The structure can include a metal trench oriented vertically and disposed between the gate structure of the PMOS transistor and the second gate structure of the NMOS transistor. The metal trench can electrically couple the gate structure and the second gate structure to form an inverter.

The structure can include the nanosheet material that includes an epitaxially grown silicon material. The structure can include the shell material that includes one of a germanium (Ge) material or a silicon germanium (SiGe) alloy material. The structure can include a layer of a second shell material disposed between the layer of the shell material and the gate dielectric. The layer of the second shell material can at least partly surround the layer of the shell material. The second shell material can be different than the shell material. The second shell material can include a charge carrier mobility that is greater than the charge carrier mobility of the nanosheet material.

The structure can include the shell material that is one of a Ge or a SiGe alloy and the second shell material that is a remaining one of the Ge or a SiGe alloy. The structure can include the shell material that includes a first SiGe alloy having a first molar ratio of silicon and germanium and the second shell material that includes a second SiGe alloy having a second molar ratio of silicon and germanium.

In some aspects, the present disclosure relates to a method. The method can include forming a nanosheet based on a layer of a nanosheet material. The method can include forming a layer of a shell material at least partly surrounding the nanosheet to form a channel of a transistor. The shell material can include a charge carrier mobility that is greater than a charge carrier mobility of the nanosheet material. The method can include forming a layer of a gate dielectric of a gate structure of the transistor over the layer of the shell material. The method can include forming a gate metal of the gate structure over the layer of gate dielectric. The gate structure can at least partly surround the channel.

The method can include forming a second nanosheet based on a second layer of the nanosheet material. The second layer can be oriented horizontally and can be disposed beneath the layer of the nanosheet material that is oriented horizontally. The method can include forming a third nanosheet formed based on a third layer of the nanosheet material. The third layer can be oriented horizontally and can be disposed beneath the second layer of the nanosheet material. The method can include forming a second layer of the shell material at least partly surrounding the second nanosheet to form a second channel of the transistor. The transistor can be a p-type metal oxide semiconductor (PMOS) transistor. The method can include forming a third layer of the shell material at least partly surrounding the third nanosheet to form a third channel of the PMOS transistor. The method can include forming the gate structure of the PMOS transistor. The gate structure can at least partly surround the second channel and at least partly surround the third channel. The gate structure can include the gate dielectric disposed between the gate metal and the second layer of the shell material. The gate structure can be disposed between the gate metal and the third layer of the shell material.

The method can include forming a fourth nanosheet for a fourth channel of an n-type metal oxide semiconductor (NMOS) transistor disposed beside the PMOS transistor. The fourth nanosheet can be formed based on the layer of the nanosheet material. The method can include forming a fifth nanosheet for a fifth channel of the NMOS transistor. The fifth nanosheet can be formed based on the second layer of the nanosheet material. The method can include forming a sixth nanosheet for a sixth channel of the NMOS transistor. The sixth nanosheet can be formed based on the third layer of the nanosheet material. The method can include forming a second gate structure. The second gate structure can at least partly surround each of the fourth channel, the fifth channel, and the sixth channel. The second gate structure can include a second gate dielectric disposed between a second gate metal of the second gate structure and the fourth nanosheet, between the second gate metal and the fifth nanosheet and between the second gate metal and the sixth nanosheet.

The method can include forming an isolation trench oriented vertically and disposed between the gate structure of the PMOS transistor and the second gate structure of the NMOS transistor. The isolation trench can electrically isolate the gate structure and the second gate structure. The method can include forming a metal trench oriented vertically and disposed between the gate structure of the PMOS transistor and the second gate structure of the NMOS transistor. The metal trench can electrically couple the gate structure and the second gate structure to form an inverter.

The method can include forming the nanosheet material to include an epitaxially grown silicon material. The method can include comprising forming the shell material to include one of a germanium (Ge) material or a silicon germanium (SiGe) alloy material. The method can include forming a layer of a second shell material disposed between the layer of the shell material and the gate dielectric. The second shell material can at least partly surround the layer of the shell material. The second shell material can be different than the shell material and include a charge carrier mobility that is greater than the charge carrier mobility of the nanosheet material.

The method can include forming the shell material to include one of a Ge or a SiGe alloy. The method can include forming the second shell material to include a remaining one of the Ge or a SiGe alloy. The method can include forming the shell material to include a first SiGe alloy having a first molar ratio of silicon and germanium. The method can include forming the second shell material to include a second SiGe alloy having a second molar ratio of silicon and germanium.

These and other aspects and implementations are described in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1-22 illustrate cross-sectional and top-down illustrations of an example process flow for fabricating transistors with shell material covered nanosheets in a two transistor structure with gate electrodes centrally located with opposite orientations, according to one or more embodiments.

FIG. 23-33 illustrate cross-sectional and top-down illustrations of an example process flow for fabricating transistors with shell material covered nanosheets in a two transistor structure with gate electrodes located at opposite end of the structure, according to one or more embodiments.

FIG. 34 is a flow diagram of an example method for fabricating transistor structures in accordance with the present solution and using techniques and features of the fabrication steps discussed and illustrated in connection with FIGS. 1-33, according to one or more embodiments.

### DETAILED DESCRIPTION

Reference will now be made to various illustrative embodiments depicted in the drawings, and specific language will be used to describe the same. It is understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processors, graphics processing units, central processing units, integrated circuits and more. For example, structures and/or circuits described herein can include a part of systems including or utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a silicon substrate. A base layer, therefore, can be a semiconductor substrate, such as a silicon substrate or any other semiconductor, ceramic, metal or other material substrate.

The process flows described herein can utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, or an NMOS device arranged beside a PMOS device, alternative configurations are contemplated. Alternative configurations can include a PMOS device over NMOS device, NMOS device over NMOS device, PMOS device over PMOS device, PMOS beside NMOS device, NMOS beside NMOS device, PMOS beside PMOS device or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), Silicon Oxyflouride. Dielectric materials can also include, for example, ceramics, glass, mica, organic and oxides of various metals.

A high-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, ruthenium, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive. For example, a 2D material can be deposited on an outer surface of a nanosheet to form a transistor channel supported by the nanosheet.

Additionally or alternatively, 2D materials to be used for forming 2D channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In2O3, SnO2, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, they can be herein described as one embodiment. However it is to be appreciated that other non-epitaxially grown materials can be utilized. Since a 2D material can be precisely deposited on an insulative sheet, this can enable a very low Dt integration build of horizontal nanosheets with high performance. It should be understood that any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheet can include an electrically insulating material that can be used as a seed layer for the 2D material(s) used in the stack. Carrier nanosheets can, in some implementations, include the materials suitable for forming a transistor channel using the nanosheet material which can include doped semiconductor material. Additionally or alternatively, a seed layer can include a material that can be deposited onto a carrier nanosheet onto which a layer of 2D material can be formed, deposited or applied.

The present disclosure can also refer to conductive oxide materials. Conductive oxides can include certain types of materials that include elements combined with oxygen to form a new material that exhibits semiconductor properties, including being able to turn off with low off state leakage current under some conditions and be highly conductive under other conditions. For example, N type conductive channels can be formed with In₂O₃, SnO₂, InGaZnO and ZnO. P type conductive channels can be formed with SnO. Using these materials, N-type and P-type transistors can be formed using conductive oxides. In some instances, conductive oxides can be used instead of or together with 2D materials, and vice versa.

The order of description or fabrication steps performed or described herein has been presented for clarity sake and as an example. The fabrication steps described herein can be performed in any suitable order. Fabrication can be included, for example, using wafer bonding techniques in which a portion of a layer stack or a transistor structure can be bonded with another portion of a layers tack or a transistor structure on another wafer. Additionally, although each of the different features, techniques, configurations described herein may be described in different places of this disclosure, it is intended that each of the concepts can be executed independently of each other or in combination with each other. Accordingly, the solutions described herein can be embodied and viewed in many different ways.

Reference will now be made to the Figures, which for the convenience of visualizing the 3D semiconductor fabrication techniques described herein, illustrate an example substrate and its deposited material layers undergoing a process flow in both top and cross-sectional views. Unless expressly indicated otherwise, each Figure represents one (or a set) of fabrication steps in an example process flow that can be used for manufacturing the devices produced by the present solution. In the top and cross-sectional views of the Figures, connections or interfaces between conductive layers or materials may be shown. However, it should be understood that these connections or interfaces between various layers and masks are merely illustrative, and are intended to show a capability for providing such connections, and they should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that any illustrated shapes, whether of the structures or features, are used as examples of the present solution and are merely illustrative and should not be considered limiting to the scope of the techniques described herein. For example, although most of the Figures can show various layers in a rectangular shaped configuration, other shapes are also contemplated, and indeed the techniques described herein may be implemented in any shape or geometry, such as circular, elliptical, or any curved or any polygonal shape. In addition, examples in which a particular number of transistors or nanosheets are shown stacked on top of one another are shown for illustrative purposes only, and for the purposes of simplicity. Indeed, the techniques described herein may provide for one to any number N stacked transistors or nanosheets. Further, although the devices fabricated using these techniques are shown as transistors, it should be understood that any type of electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices. For example, a plurality of PMOS and NMOS devices can be fabricated, using the techniques described herein, in a plurality of rows and columns on a substrate and a plurality of stacks of PMOS and NMOS devices can be stacked on top of such rows and columns of NMOS and PMOS devices.

The present solution relates to transistor structures that can include side-by-side 3D NMOS and PMOS transistors fabricated using horizontally oriented nanosheets and processes for fabricating such transistor structures. The nanosheets can include epitaxially grown materials, such as intrinsic epitaxially grown silicon, or other semiconductors, such as silicon germanium (SiGe). The present solution can coat or cover the nanosheets using another epitaxially grown material to form a shell layer around the nanosheet. The material forming the shell layer can include properties that can improve the performance of the channel, such as a particular charge mobility. The material forming the shell layer can include, for example, Ge or SiGe, and can be disposed between the nanosheet and the gate dielectric of the gate structure.

The present solution can enable an improved circuit density using a compact upsilon nanosheet design and can include u-shaped nanosheets. Shells, or shell layers, can be epitaxially grown and improve the performance of the NMOS and PMOS transistors structures. The present solution can include a 3D isolation trench between the adjacent transistors to provide electrical isolation as well as a metal trench between the gate structures of the two adjacent transistors to electrically short their gates and form inverters. The present solution can also include isolation inserts of selective dielectrics that can allow transistors (e.g., NMOS and PMOS) to have separate channel release and different high-k and gate metal materials for improved performance across the NMOS and PMOS structure.

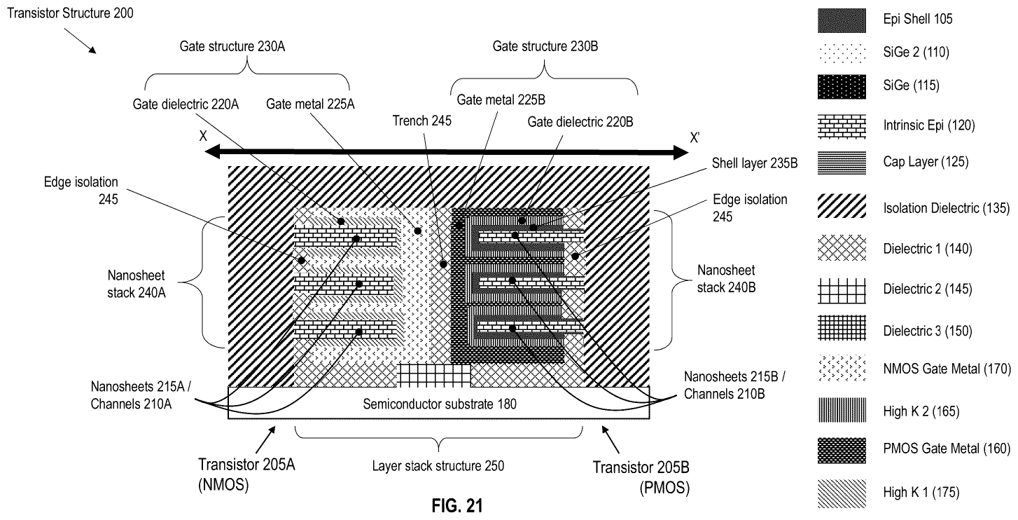

Prior to describing the fabrication steps for manufacturing the structures of the present solution, it may be useful to first briefly overview an example side-by-side 3D NMOS and PMOS structure fabricated in accordance with the methods and techniques of the present solution. As an illustrative example, FIG. 21 includes a cross-sectional view of transistor structure 200 that can include an NMOS transistor 205A and a PMOS transistor 205B that can be fabricated on a semiconductor substrate 180. Transistor structure 200 can be fabricated using the process techniques described herein applied to the layer stack structure 250. On the left side of the transistor structure 200, nanosheet stack 240A can be used to form a transistor 205A that can include three channels 210A formed using three nanosheets 215A. Each channel 210A can be surrounded by a gate structure 230A, which can include a gate dielectric 220A that is surrounded by gate metal 225A. On the right side of the transistor structure 200, nanosheet stack 240B can be used to form transistor 205B, which can include three channels 210B formed using three nanosheets 215B. Each nanosheet 215B can be covered by a shell layer 235B to improve the performance of the transistor 205B. Each shell layer 235B of transistor 205B can be surrounded by a gate structure 230B, which can include a gate dielectric 220B that is surrounded by gate metal 225B.

As will be further described below, transistors 205A and 205B can be formed side by side using same material layers for forming horizontally oriented nanosheets 215A. As a result, transistors 205 can include nanosheets 215A and 215B comprising the same nanosheet material. Layers of material above and below the nanosheet material layers can be removed during the fabrication process (e.g., sacrificial layers), allowing for other materials (e.g., gate structure 230) to fill the void.

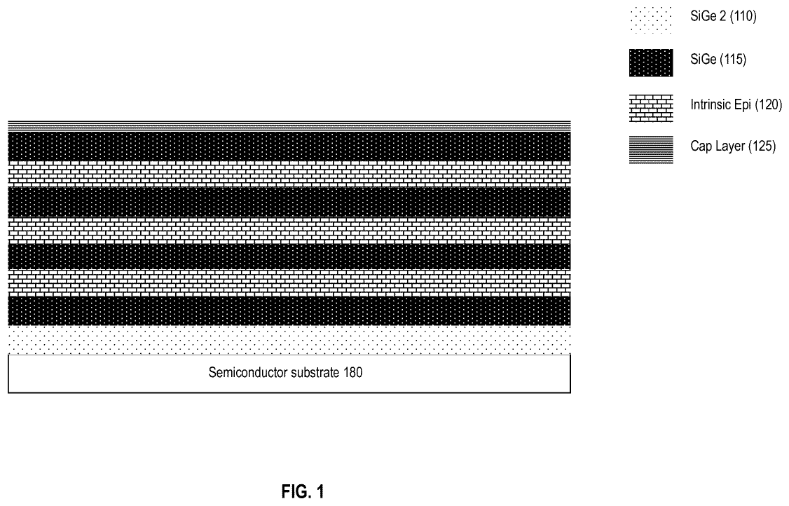

The present solution can relate to an example process flow for fabricating transistors having channels formed with upsilon nanosheets covered by single crystal epitaxially grown shells in PMOS devices with gate electrodes that are centrally located in the transistor structure. For example, the process flow can provide a resulting structure 200 that can include side-by-side transistors 205, such as NMOS transistor 205A and PMOS transistor 205B, where the gate structures 230 of the transistors 205A and 205B are formed in the middle or central portion of the transistor structure 200, such that the two gate electrodes (e.g., gate structures 230) are turned away from each other and towards their respective channels 210. Transistor structure 200 with outward gate electrodes may be utilized, as described in connection with FIGS. 1-22.

Referring now to the start of the fabrication process of the transistor structure 200, FIG. 1 refers to an initial stack of material that can be used for fabricating transistor structure 200. FIG. 1 depicts a cross-sectional view of an example layer stack having several layers of materials. The layer stack can be formed on a substrate 180. The layer stack can include multiple material layers deposited on top of each other. For example, a first layer of material deposited on a substrate 180 can include a layer of SiGe 2 (identified in the illustration as material SiGe 110). On top of the SiGe 110, a first of the three layers of SiGe (identified in the illustration as material SiGe 115) can be deposited. SiGe 115 can include epitaxially grown material and can include non-doped (e.g., resistive) or doped (e.g., conductive or semi-conductive) material. On top of SiGe 115, a first of the three layers of intrinsic epi (identified in the illustration as intrinsic epi 120) can be deposited. Intrinsic epi 120 can include, for example, an epitaxial silicon intrinsic layer and can be referred to as an intrinsic epitaxially grown silicon layer. Intrinsic epi 120 can include a non-doped, and therefore resistive, silicon material. Alternatively or additionally, intrinsic epi 120 can include doped, and therefore, conductive or semi-conductive material. On top of the first layer of intrinsic epi 120, a second layer of SiGe 115 can be formed, followed by a second layer of intrinsic epi 120, followed by a third layer of SiGe 115, followed by a third layer of intrinsic epi 120 layer, which can also be followed by a fourth layer of SiGe 115. As a result, three layers of intrinsic epi 120 can be deposited, where each layer is surrounded above and below by a layer of SiGe 115 material, such that intrinsic epi 120 and SiGe 115 layers are layered on top of each other in an alternating fashion. On top of the fourth SiGe 115 layer, a cap layer (identified in the illustration as cap layer 125) can be deposited to complete the layer stack of materials from which the transistor structure 200 is to be fabricated.

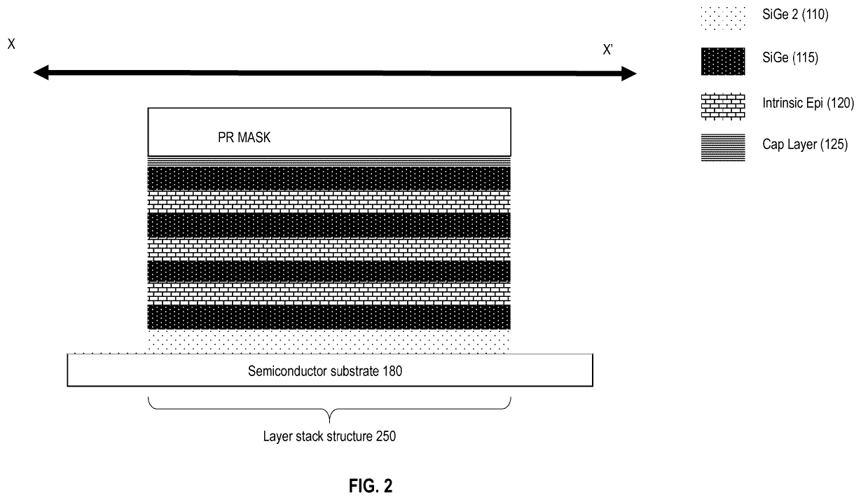

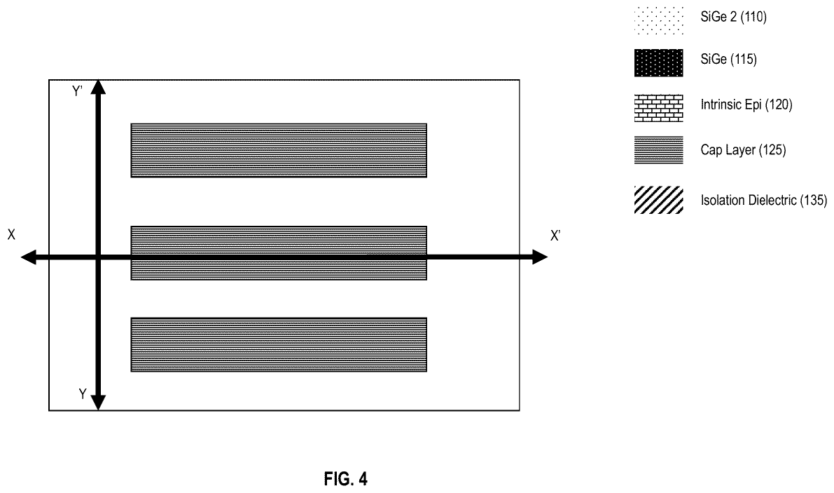

FIG. 2 illustrates a cross-sectional view of the layer stack on top of which a photoresist (PR) mask is applied to perform an etch. The PR mask can protect and shape the layer stack structure 250 in which transistor structure 200 is to be fabricated. The layer stack structure 250 can be formed by etching out the surrounding material using the directional etch of the areas not protected by the PR mask. After the PR mask is layered on top of the layer stack, an etch, such as a directional downward etch, can be performed outside of the PR mask to define the initial X-Y dimensions of the layer stack portion in which the 3D transistor structure 200 is to be formed. The Y dimensions of the layer stack can be visible, for example, in the top view of FIG. 4, illustrated and discussed below.

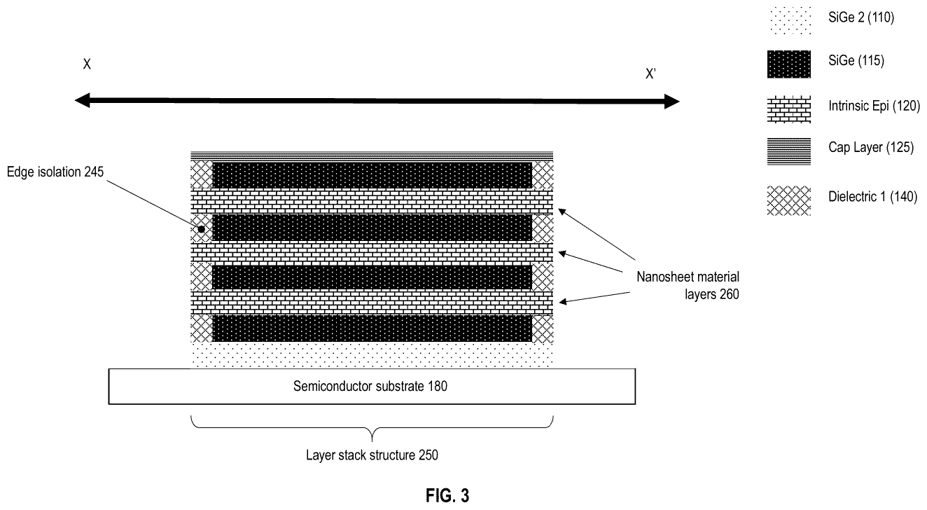

FIG. 3 illustrates a cross-sectional view of the layer stack following the completion of several fabrication steps. First, a photoresist strip can be performed to remove the PR mask illustrated in FIG. 2. After the photoresist strip, an indent etch of SiGe 115 layers can be performed. The indent etch can be performed simultaneously on the outer surfaces of the SiGe 115 layers that are exposed on the sidewalls of the layer stack. The indent etch be performed on the outer edges of the SiGe 115 layers from the openings at the distal ends of the layer stack structure 250. The indented etched layers can be made shorter by some fraction of their total horizontal length with respect to the cap layer 125, intrinsic epi 120 and SiGe 110 layer, which are not etched. As a result, cap layer 125, intrinsic epi 120 and SiGe 110 layers can project over the outer edges of the SiGe 115, forming hollow voids in the areas from which SiGe 115 was indent etched.

Following the indent etch of SiGe 115, a deposition fill can be performed by dielectric 1 (identified in the illustration as dielectric 140). The deposition fill by dielectric 140 can fill in the indent etched portions (e.g., the voids) of the indent etched out outer portions of the SiGe 115 layers to form edge isolation 245. Once the trench is filled with the dielectric 140 material, a downward directional etch can be performed using the cap layer 125 as the mask in order to fill the incident etched portion (e.g., indent etch portion) of the layer stack with dielectric 140. As a result, the material layers of SiGe 115 can be completely surrounded by edge isolation 245 formed by dielectric 140. For example, indent etch of the SiGe 115 layers can be performed on all four sides of the layer stack structure 250 (e.g., in the X-Y plane as viewed from the top), after which, using dielectric 140, edge isolation 245 can be formed all around (e.g., on all four sides) of the SiGe 115 to fill the voids. Once the layer stack structure 250 is processed into the final transistor structure 200 these SiGe 115 layers can be electrically isolated on their outer surfaces by the edge isolation 245 on the outer surfaces.

Remaining exposed between the edge isolations 245 are nanosheet material layers 260, which can include intrinsic epi 120. While in the illustrated example, the nanosheet material layers 260 are made from intrinsic epi 120, it is understood that other materials can be used, such as Ge, SiGe or any other dielectric or semiconductor.

FIG. 4 illustrates a top-down view of the layer stack following the completion of fabrication steps described in FIG. 3. As shown in FIG. 4, from a top-down perspective multiple rectangular shapes exposing cap layer 125 material can indicate multiple 3-D rectangular prismatic layer stack structures 250. The X-axis illustrates a point of cross-section in the illustrated cross-sectional views, while Y axis shows a direction along which other cross-sections can be made. In the illustrated embodiment, layer stack structures 250 that are same or similar to the one shown in the X-cross-section can be found above and below the cross-sectioned layer stack structure 250 and can be processed simultaneously.

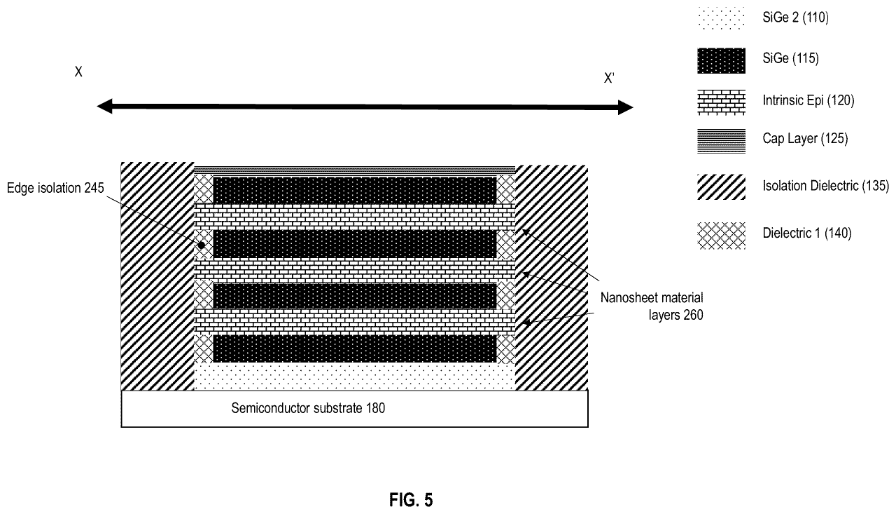

FIG. 5 illustrates a cross-sectional view of the layer stack structure 250 completing an isolation deposition by filling the etched out trench around the layer stack structure with isolation dielectric 135. This step can be followed by a chemical mechanical planarization or polishing (CMP), to remove the surplus material above the cap layer 125. At the end of this step, nanosheet material layers 260, already isolated by edge isolations 245 can be further buried in dielectric 135.

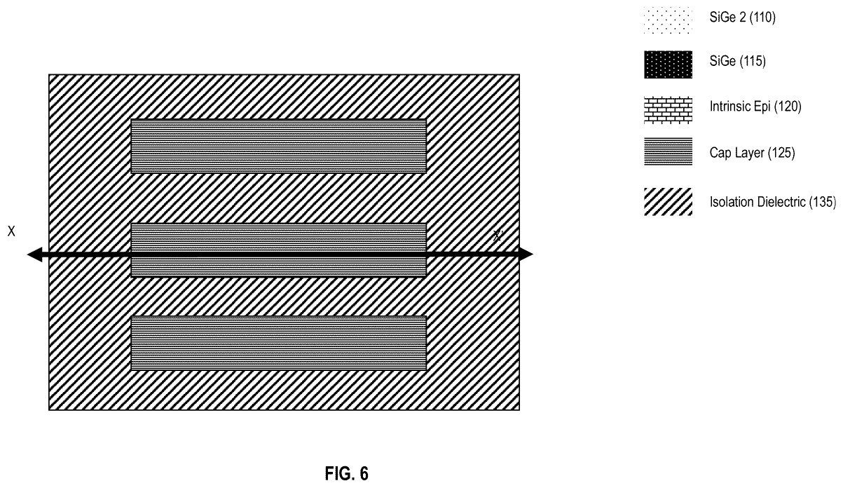

FIG. 6 illustrates a top-down view of the layer stack structures 250 following the completion of the fabrication steps described in FIG. 5. As shown in FIG. 6, rectangular shapes of cap layers 125 that were earlier discussed in connection with FIG. 4 are now surrounded by isolation dielectric 135. At this point, layer stack structures in which transistors are to be formed are buried in isolation dielectric 135 material, whose top surface can be made flush with the cap layer 125 of the layer stack.

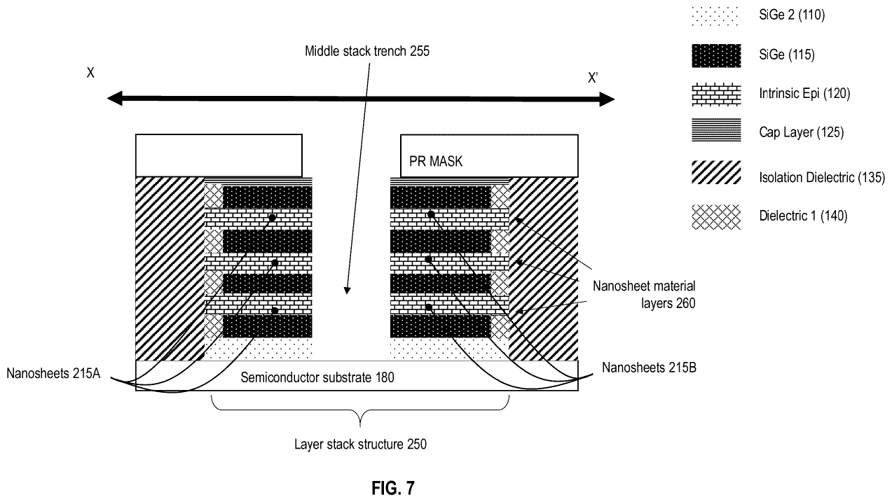

FIG. 7 illustrates a cross-sectional view in which a PR mask is applied, covering the two end portions of the layer stack structure 250, and exposing the middle portion of the layer stack structure 250 in which a downward etch is to be performed. For example, a PR mask can cover a middle portion of the layer stack structure 250 that corresponds to a fraction of the length the layer stack structure 250, such as a fifth, a quarter, a third or a half of the length of the layer stack structure 250, exposing the middle portion for etching. A directional downward etch can then be performed through the entire exposed middle portion of the layer stack structure 250 until semiconductor substrate 180 is reached. The etched out middle portion can result in a vertical middle stack trench 255 that is formed the middle section of the layer stack structure 250. As a result, from the three nanosheet material layers 260, three nanosheets 215A can now be formed on the left side and three nanosheets 215B can be formed on the right side. The nanosheets 215A and 215B can be separated by the middle stack trench 255, which as will be discussed further below, can be filled with other materials or structures.

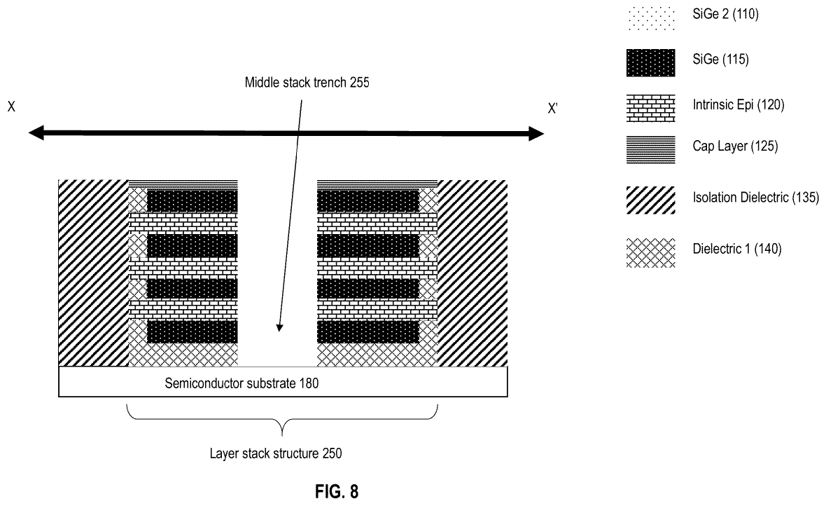

FIG. 8 illustrates a cross-sectional view of the layer stack in which the PR mask and the SiGe 110 material on the semiconductor substrate 180 are removed. The removal of SiGe 110 layer can be implemented by selectively etching of SiGe 110 through the middle stack trench 255 that can be created in connection with FIG. 7. The empty space left where SiGe 110, can be filled in by dielectric 140 material and the etch can be aligned to cap layer 125

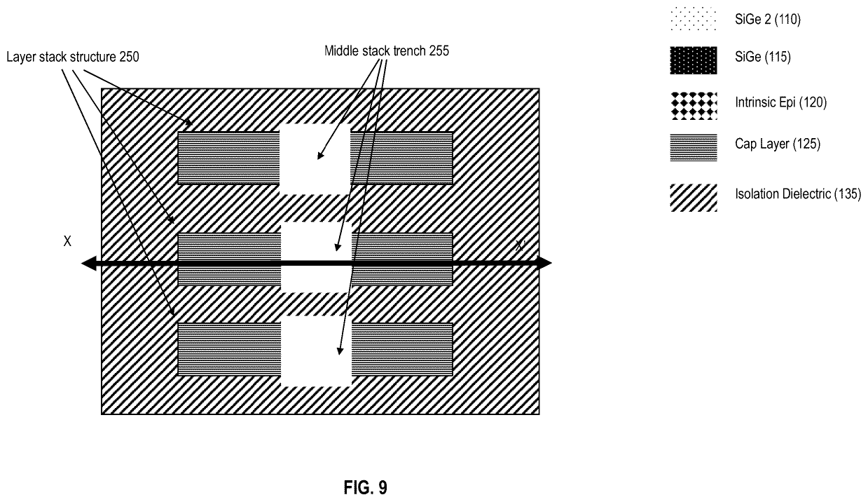

FIG. 9 illustrates a top-down view of the layer stack following the completion of the fabrication steps described in FIG. 8. As shown in FIG. 9, middle stack trenches 255 are directionally etched downward through the middle portion of the layer stack structures 250 indicated by the rectangular shaped cap layers 125. As illustrated, middle stack trenches 255 can be etched through the entire layer stack structures 250 and to the substrate 180 and can also extend partially into isolation dielectric 135 that surrounds the layer stack structures 250. Etching the middle stack trenches 255 beyond the layer stack structures 250 can ensure isolation between the transistor 205 device to be built on one side of the layer stack structure 250 and transistor 205 device to be built in the other side of the layer stack structure 250.

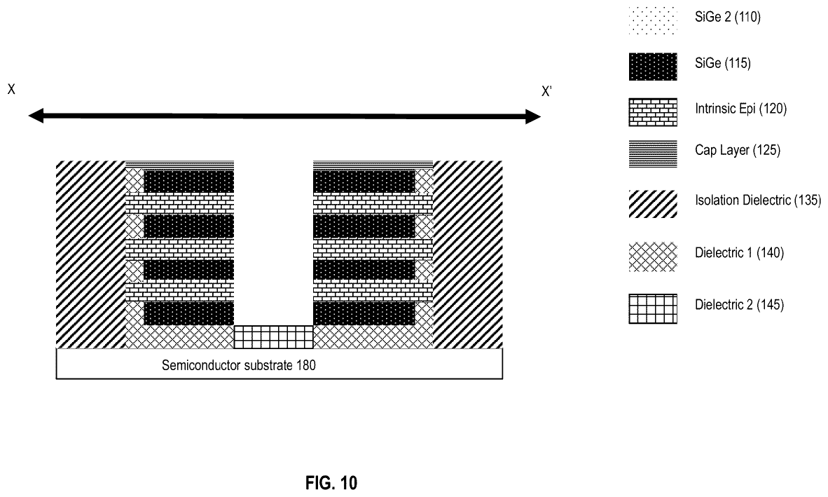

FIG. 10 illustrates a cross-sectional view of the layer stack in which dielectric 2 (identified in the illustration as dielectric 145) is deposited at the bottom layer to fill in the space inside the middle stack trench 255 in which SiGe 110 material used to be deposited. Dielectric 145 can then fill out the space on top of the substrate 180 and up to the bottom surface of the SiGe 115 layer. Upon completion of this step, a CMP can be performed.

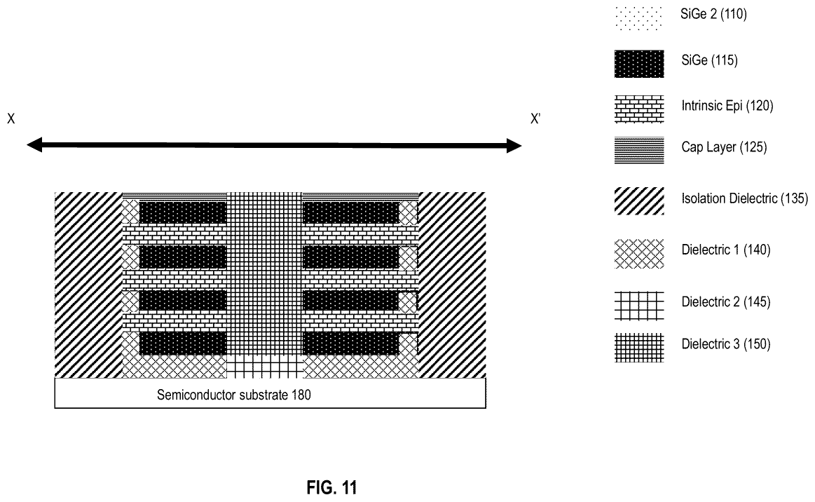

FIG. 11 illustrates a cross-sectional view of the layer stack in which dielectric 3 (identified in the illustration as dielectric 150) is deposited to fill up the middle stack trench 255. Dielectric 150 can interface with the top of the dielectric 145 at the bottom and with the sidewalls of the SiGe 115 and intrinsic epi 120 layers. CMP can be performed to remove any surplus material.

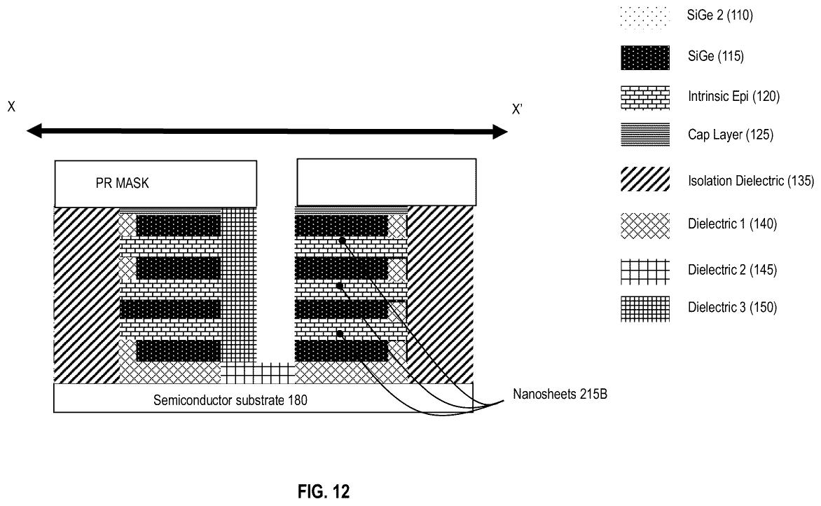

FIG. 12 illustrates a cross-sectional view of the layer stack in which PR mask is applied to expose one side of the dielectric 150 material filling the middle stack trench 145 (e.g., the right side). Then, a directional downward etch of the exposed side (e.g., right side) of the dielectric 150 in the middle stack trench 145 can be performed to create a vertical hollow cavity along the interior sidewalls of the nanosheets 215B.

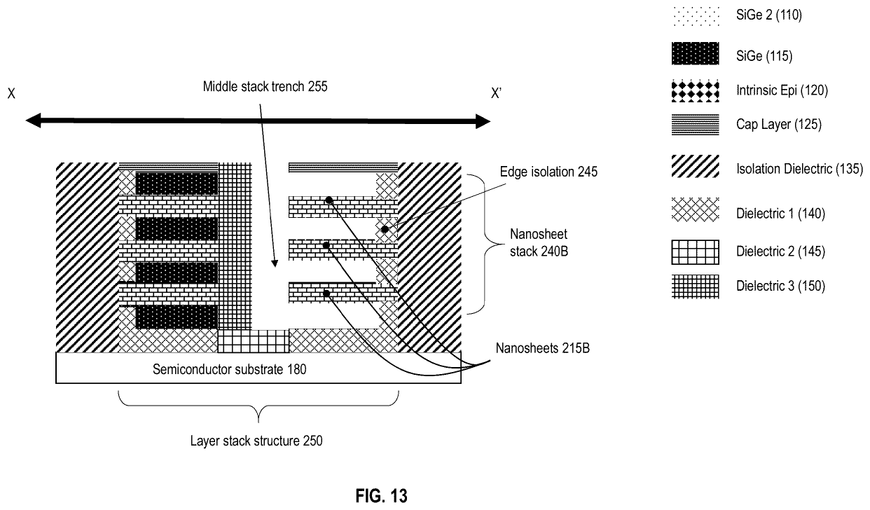

FIG. 13 illustrates a cross-sectional view of the layer stack structure 250 in which the right side portion of the SiGe 115 layer is removed from the right-side 3D nanosheet stack 240B. SiGe 115 can be removed via selective etching process directed to these and which can be implemented through the opening in the middle stack trench 255. By etching SiGe 115, SiGe 115 is used as a sacrificial layer in the nanosheet stack 240B in which transistor 205B is to be formed. As a result, intrinsic epi 120 can remain suspended from the isolation dielectric 135 material and edge isolations 245 formed with dielectric 140, at the right side and be devoid of any material support beneath, above and to the left of them. The remaining three intrinsic epi 120 structures can now form nanosheets 215B of the nanosheet stack 240B.

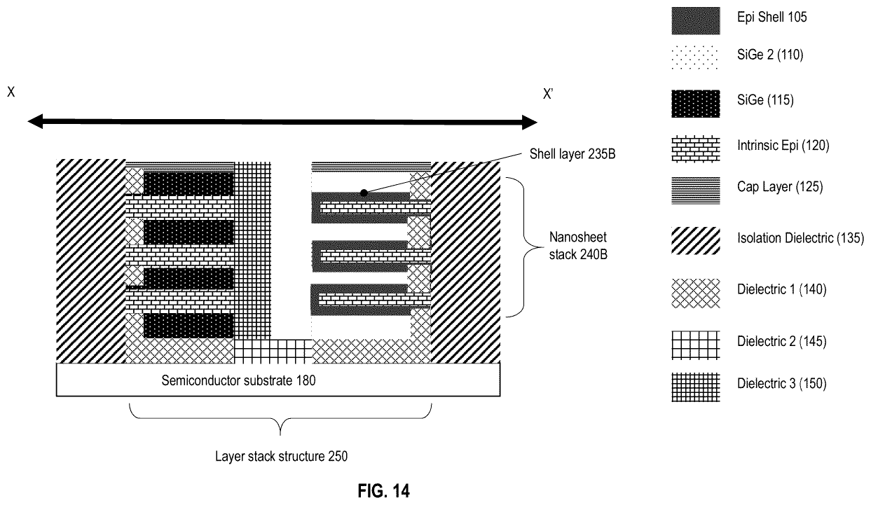

FIG. 14 illustrates a cross-sectional view of the layer stack structure 250 in which a layer of epitaxial shell material (identified in the illustration as epi shell 105) is grown, deposited, coated or otherwise formed on the exposed surfaces of the nanosheets 215B. Epi shell 105 can form a coating or a layer of epi shell material that can be referred to as a shell layer 235. Material of the epi shell 105 can include material properties that are different from those of the material in the nanosheet material layers 260. Epi shell 105 can include charge mobility of holes or electrons in the material of the epi shell 105 that is different than the charge mobility of the holes or electrons in the material of the nanosheet material layers 260. For example, Epi shell 105 material can include charge mobility that is higher than the charge mobility of the material in the nanosheet material layers 260. Epi shell 105 material can include charge mobility that is lower than the charge mobility of the material in the nanosheet material layers 260. Epi shell 105 material can include charge mobility that is the same as the charge mobility of the material in the nanosheet material layers 260. Epi shell 105 can include doped material, such as n-type or p-type doped material. Epi shell 105 can include electrical resistivity or conductivity that is different from that of the material in the nanosheet material layers 260. Epi Shell 105 can include material that can be selectively epitaxially grown on the surface of intrinsic epi 120 material. Epi Shell 105 can include materials suitable for PMOS channels or structures, such as Ge or SiₓGe_{y} (e.g., any ratio of silicon and germanium to form any SiGe alloy, Si₍₁₋ₓ₎Ge₍ₓ₎). Epi shell 105 can be used on nanosheets 215B of PMOS transistor 205B. Additionally or alternatively, Epi shell 105 can be suitable for NMOS channels or structures and can be used with nanosheets 215A for an NMOS transistor 205A. Alternatively or additionally, intrinsic epi 120 base cross-sectional area can be reduced by either silicon etch or oxide growth, followed by strip. This can be done, for example, in order to create the space for the epi shell 105 or to maintain the same size of channels 210A and 210B.

Shell layers 235 can be applied in any transistors 205A and 205B, such as for example on any nanosheets 215A or 215B of any NMOS or PMOS transistors. In some implementations, multiple shell layers 235 can be formed on a nanosheet 215. For example, a first layer of epi shell 105 material can form a first shell layer 235 and a second epi shell 105 material can form a second shell layer 235 on top of the first shell layer 235. The first and second shell layers 235 can include different materials. For example, a first shell layer 235 grown, deposited or otherwise formed on one or more surfaces of a nanosheet 215 can include epi shell 105 material, such as Ge, while a second shell layer 235 formed on top of the first shell layer 235 can include SiGe material. For example, a first shell layer 235 grown, deposited or otherwise formed on one or more surfaces of a nanosheet 215 can include a first epi shell 105 material, such as Si₍₁₋ₓ₎Ge₍ₓ₎ forming an alloy of a first ratio of Si and Ge materials, while a second shell layer 235 formed on top of the first shell layer 235 can include Si_{(1-y)}Ge_{(y)} alloy of a different ratio of Si and Ge materials.

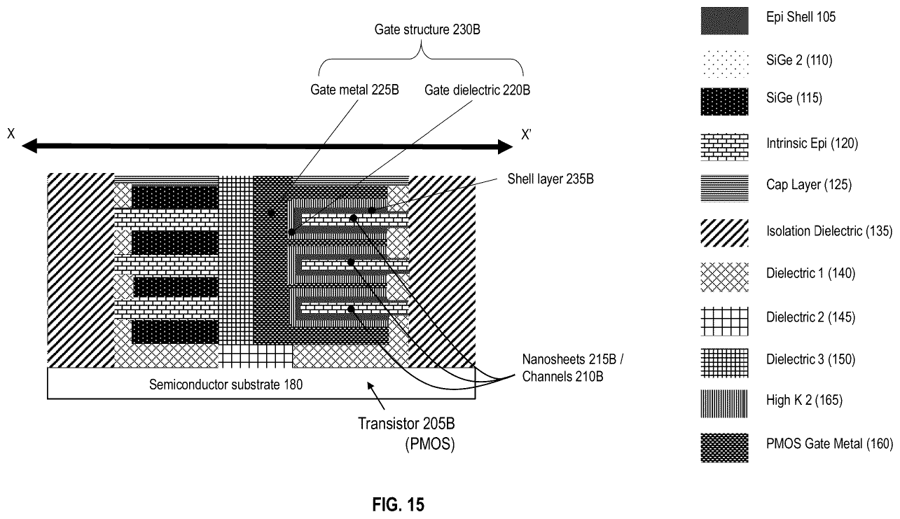

FIG. 15 illustrates a cross-sectional view of the layer stack in which the void left by the SiGe 115 layers removed in FIG. 12 is filled first with a thin layer of high-k 2 165 material coated on the exposed surfaces of intrinsic epi 120 nanosheets 215B, followed by a filling of PMOS gate metal 160 to form gate metal 225B. First, a layer of high-k 2 165 material can be selectively coated on the exposed surfaces of the SiGe 115 nanosheet 215B to create a gate dielectric 220. Once the nanosheets 215B are coated with high-k 2 165 to form gate dielectric 220B, PMOS gate metal 160 can fill the remainder of the void, above, below and in between the SiGe nanosheets 215B, which completes the gate structure 230B. At this point, channels 210B of transistor 205B are formed using nanosheets 215B and the PMOS transistor device 205B on the right side of the layer stack structure 250 is completed.

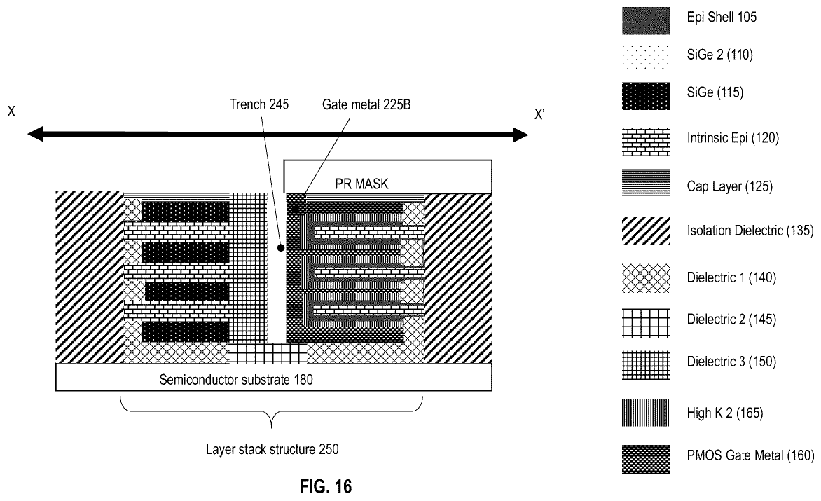

FIG. 16 illustrates a cross-sectional view of the layer stack in which a dielectric PR mask can be placed on the other side (e.g., right side) of the layer stack structure 250 in order to downward etch through the end portion (e.g., the right side) of the PMOS gate metal 160 forming the gate structure 230B on the left side of the layer stack structure 250. At this point, the process etches a vertical downward trench 245, so as to be able to either isolate the transistors 205 from each other by inserting a dielectric material into the trench 245, or electrically short the transistors 205 by inserting metal into the trench 245.

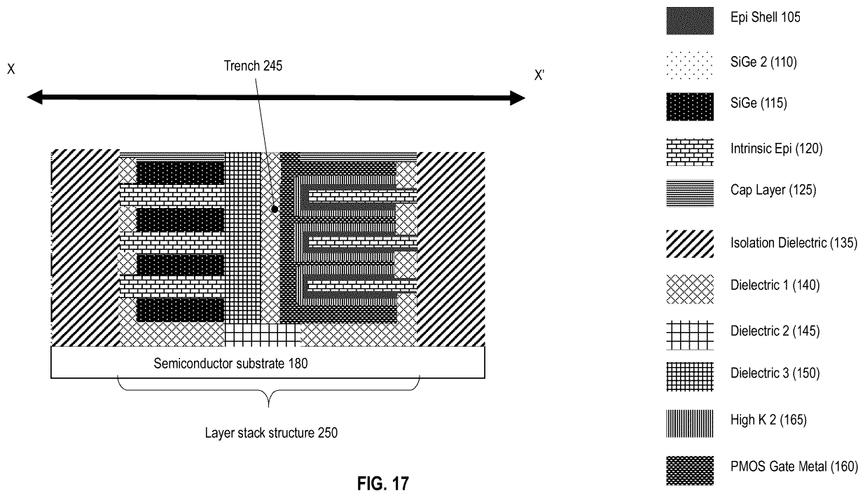

FIG. 17 illustrates a cross-sectional view of the layer stack structure 250 in which trench 245 is filled with dielectric 140. By filling the trench 245 with dielectric 140, the resulting transistor structure 200 includes two side-by-side transistors 205 that are electrically isolated from each other. Alternatively, as will be discussed further below, if trench 245 is filled with a metal, then the gate structures 230 of the two transistors 205 can be shorted together. After the dielectric 140 deposition, a CMP can be performed.

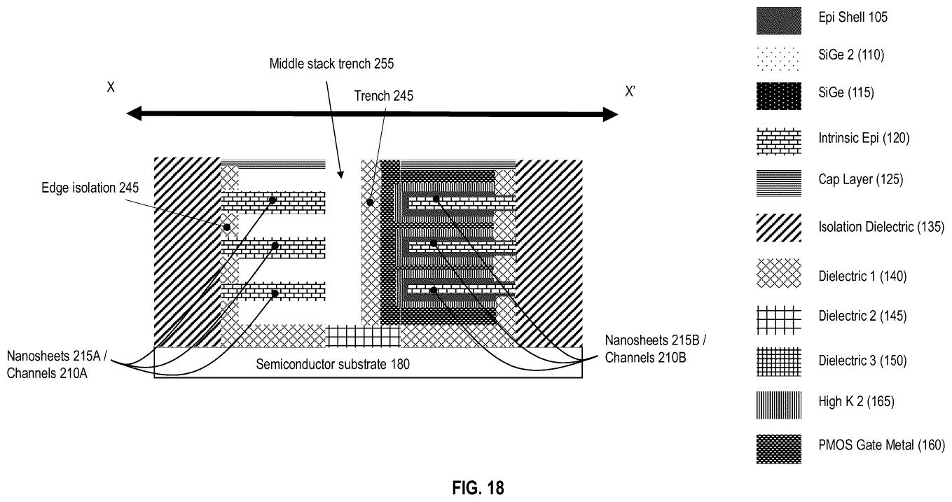

FIG. 18 illustrates a cross-sectional view of the layer stack structure 250 from which dielectric 150 can be etched out from the middle stack trench 255 leaving the dielectric 140 filling in the trench 245 intact. Once dielectric 150 is removed, SiGe 115 layers can be removed. The removal of SiGe 115 layers can be completed through selective etches via the opening in the middle stack trench 255 made with the fabrication steps in connection with FIGS. 12-13. Upon removal SiGe 115 layers, horizontal nanosheet structures made from intrinsic epi 120 material on the left side of the layer stack structure 250 can remain suspended from isolation dielectric 135 or edge isolations 245 on their left side. The remaining three intrinsic epi 115 suspended horizontal structures can stand without any material above, below or to the right of them and can now form nanosheets 210A of the nanosheet stack 240A.

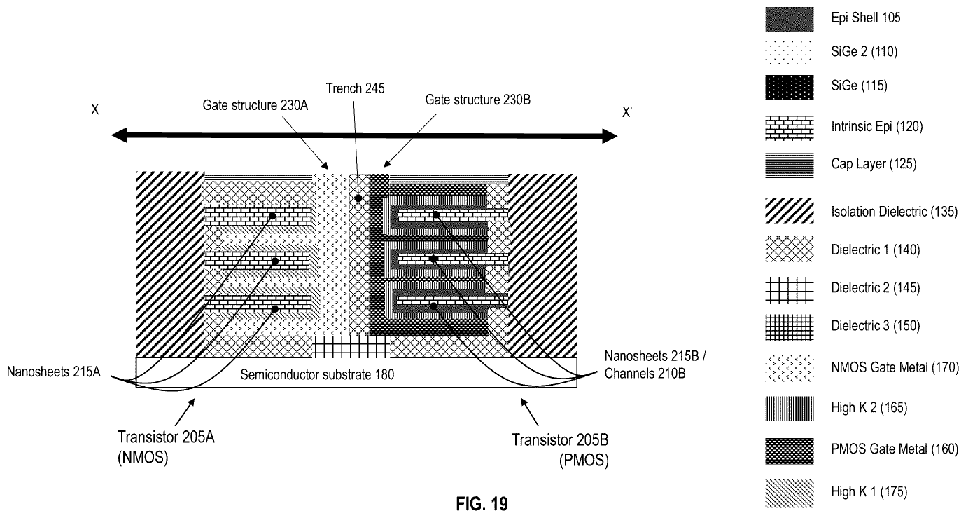

FIG. 19 illustrates a cross-sectional view of the transistor structure 200 in which high-k 175 can be coated on nanosheets 215A to form gate dielectric 220A and NMOS gate metal 170 can be filled into the open space to form a gate metal 225A, thus completing an NMOS gate structure 230A. Similar to the fabrication steps performed in connection with FIG. 15 discussed in connection with transistor 205B formation, a coating of high-k 175 can be selectively deposited on all exposed surfaces of the intrinsic epi 120 nanosheets 215A to form gate dielectric 220A. On top of the high-k 175 deposited layer, NMOS gate metal 170 can be deposited so as to fill in the interior volume all around the intrinsic epi 120 nanosheets 215A and form the gate metal 220A. As a result gate structure 230A can surround intrinsic epi 120 nanosheets 215A from the top, bottom and side surfaces, just as with gate structure 230B. At this point, channels 210A of transistor 205A are formed using nanosheets 215A and gate structure 230A is thereby completing the formation of NMOS transistor 205A in the nanosheet stack 240A. After completing transistor 205A, CMP can be performed to remove the surplus material. At this point, transistors 205A and 205B are formed side-by-side and separated by the trench 245 that is filled with dielectric 140 for electrical isolation.

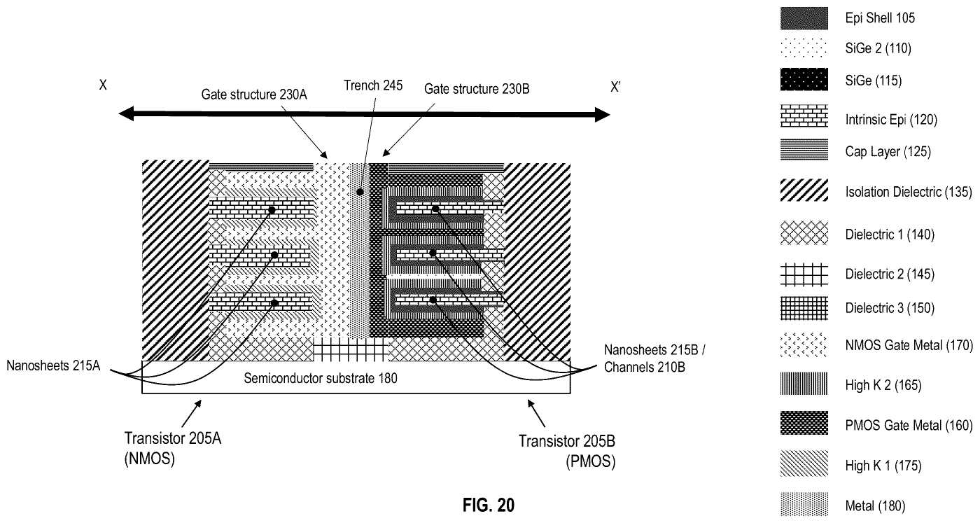

FIG. 20 illustrates a cross-sectional view of the transistor structure 200 in which trench 245 is filled with metal 180 to short the gate structure 230A of transistor 205A with the gate structure 230B of the transistor 205B. The resulting structure can form a transistor circuit, such as an inverter.

FIG. 21 illustrates a cross-sectional view of the completed transistor structure 200 in which transistor 205A and transistor 205B are covered with a layer of isolation dielectric 135 to electrically isolate the transistor structure 200 (e.g., transistors 205A and 205B) from other transistor structures 200. Upon completion of this step, CMP can be performed to remove any surplus material. The resulting layer stack structure 250 can include NMOS transistor 205A and PMOS transistor 205B along with all the features discussed earlier.

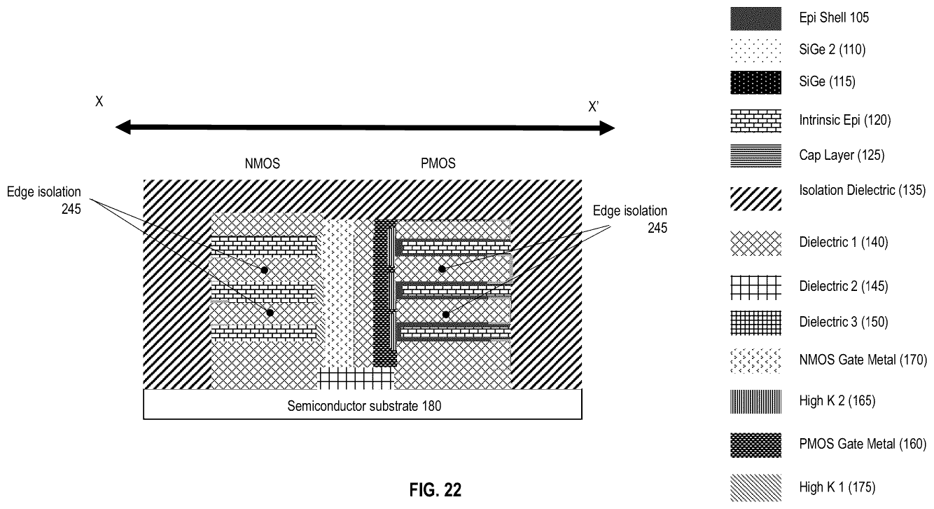

FIG. 22 illustrates a cross-sectional view of the completed transistor structure 200 in which 205A and transistor 205B are cross sectioned along the edge or near the edge of the layer stack structure 250 (e.g., near the front or the rear of the transistor structure 200). As illustrated, cross-sections of the transistor structure 200 shows that gate structures 230A and 230B are not present (e.g., at the or near the edge) because at those locations, edge isolations 245 are disposed. Therefore, gate structures 230A and 230B are located near the center of the layer stack structure 250, while nanosheet material layers 260 at the outer portions are isolated by the edge isolation 245 as formed in connection with techniques described in FIG. 3.

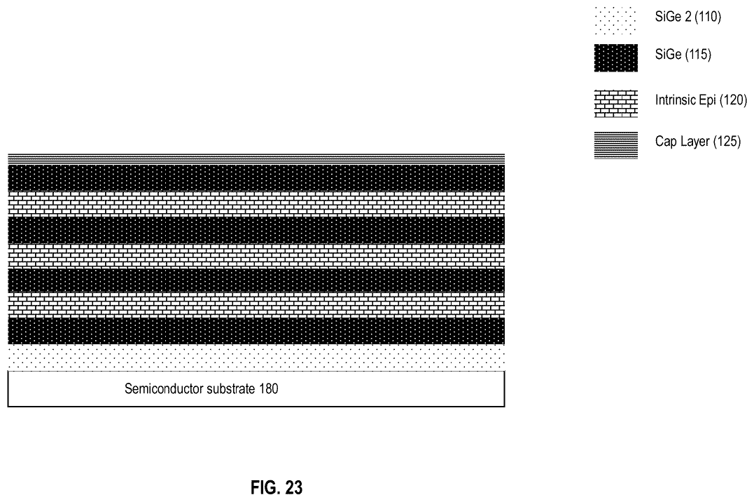

The present solution can relate to a process flow for fabricating performance 3D channels with upsilon nanosheets using single crystal epi shell for PMOS devices with outward gate electrodes. The resulting structure 200 can include side-by-side transistors 205, such as NMOS transistor 205A and PMOS transistor 205B, where the gate structures 230 of the transistors are formed on the opposite ends of the transistor structure 200. Transistor structure 200 with outward gate electrodes can be provided and discussed in connection with FIGS. 23-33.

For example, referring to FIG. 23, the same layer stack as described in connection with FIG. 1 can be used. The layer stack of FIG. 23 can include three intrinsic epi 120 layers (e.g., nanosheet layers) separated by SiGe 115 layers and covered by a cap layer 125, just as described in connection with FIG. 1.

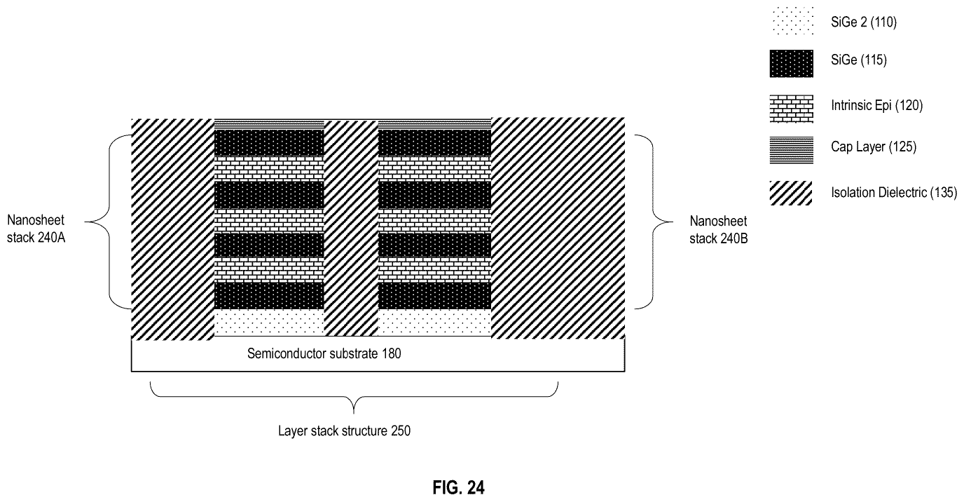

FIG. 24 illustrates a cross-sectional view of the layer stack structure 250 in which isolation PR masks can be used to directionally downward etch vertical trenches on both ends of the layer stack structure 250 and through the middle of the layer stack structure 250. The resulting layer stack structure 250 can include a nanosheet stack 240A separated from the nanosheet stack 240B by an isolation dielectric 135. Isolation dielectric 135 can electrically isolate the gate structures 230 of the two transistors 205 by filling out the entire layer stack structure 250. Isolation dielectric 135 can be levelled off with the cap layer 125 using a CMP.

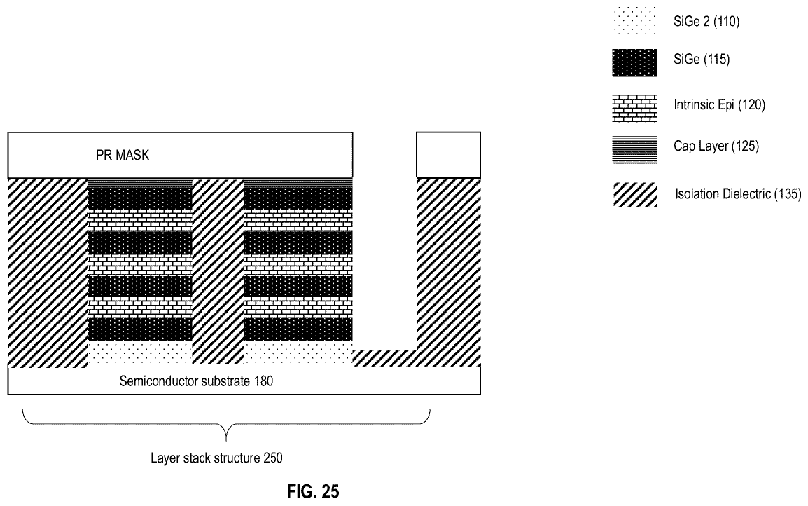

FIG. 25 illustrates a cross-sectional view of the layer stack structure 250 in which PR mask is used to directionally downward etch a portion of the isolation dielectric 135 that borders the right of the upsilon nanosheets in the nanosheet stack 240B. The etch can proceed down until the etch reaches the SiGe 110 layer at the bottom of the stack. The resulting vertical trench can expose the right side of the right side nanosheet stack 240B.

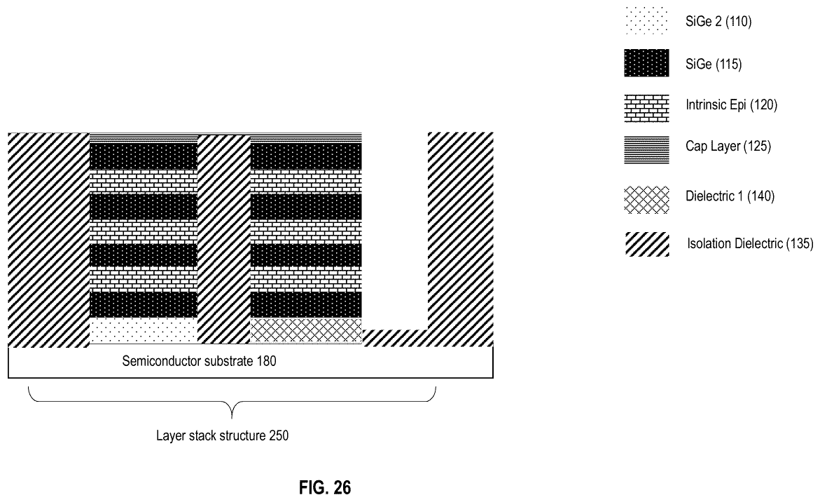

FIG. 26 illustrates a cross-sectional view of the layer stack structure 250 in which PR mask is removed and SiGe 110 layer at the bottom is removed. As illustrated, only the SiGe 110 layer portion in the right side nanosheet stack 240B is removed.

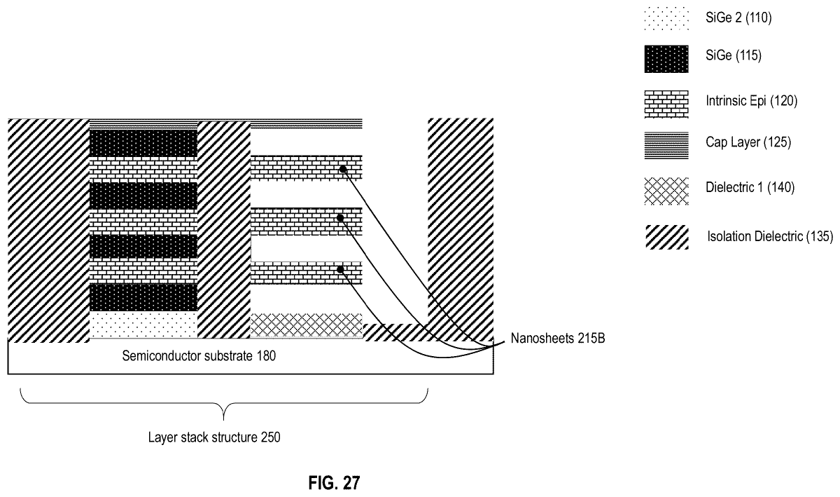

FIG. 27 illustrates a cross-sectional view of the layer stack structure 250 in which intrinsic epi 120 nanosheets 215B remain once SiGe 110 layers are removed. The nanosheets 215B can be attached to the isolation dielectric 135 on their left side, for example, and the nanosheets 215B can be suspended without any material beneath, above or to the right of the nanosheets 215B. The techniques implemented at this step can be same as those implemented in connection with FIG. 13, described earlier.

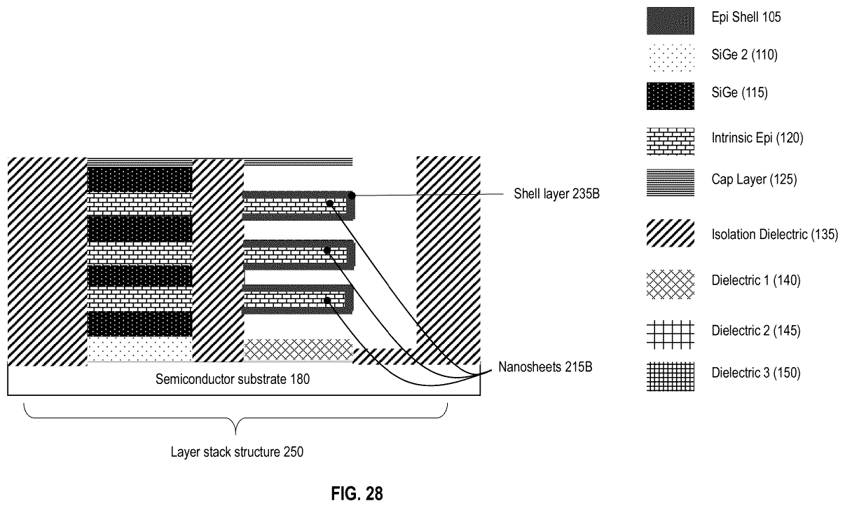

FIG. 28 illustrates a cross-sectional view of the layer stack structure 250 in epi shell 105 layers can be grown, deposited, or otherwise formed on the exposed surfaces of the intrinsic epi 120 material of the nanosheets 215B. Epi shell 105 can be grown, formed, or coated as a thin film and form a shell layer 235B on the nanosheets 215B. The techniques implemented at this step can be same as those implemented in connection with FIG. 14, as described above herein.

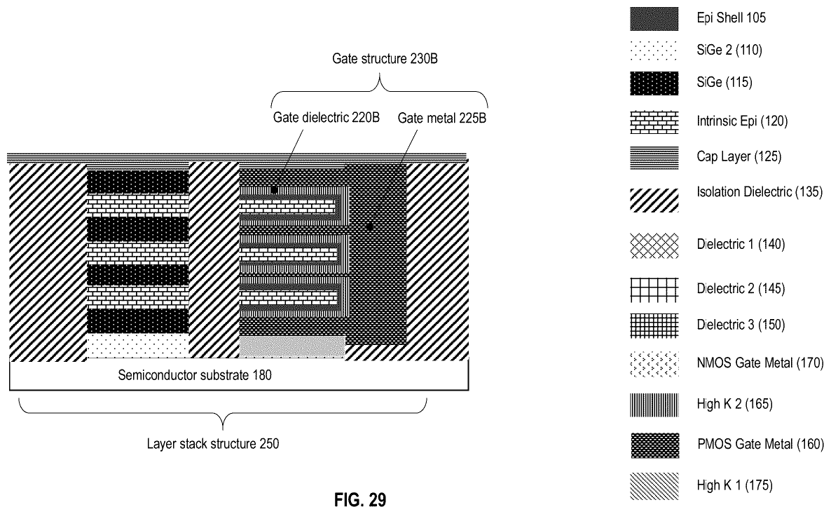

FIG. 29 illustrates a cross-sectional view of the layer stack structure 250 in which a gate dielectric high-k 2 165 can be deposited on top of the epi shell 105 material forming shell layers 235B on nanosheets 215B to form gate dielectric 220B. Then, on top of the gate dielectric 220B, PMOS gate metal 160 can be deposited to fill in the gaps between the intrinsic epi 120 nanosheets 215 and in the void left by the etched out trench. At this stage gate structure 230B, channels 210A and transistor 205A can be finalized. The techniques implemented at this step can be same as those implemented in connection with FIG. 15, discussed earlier.

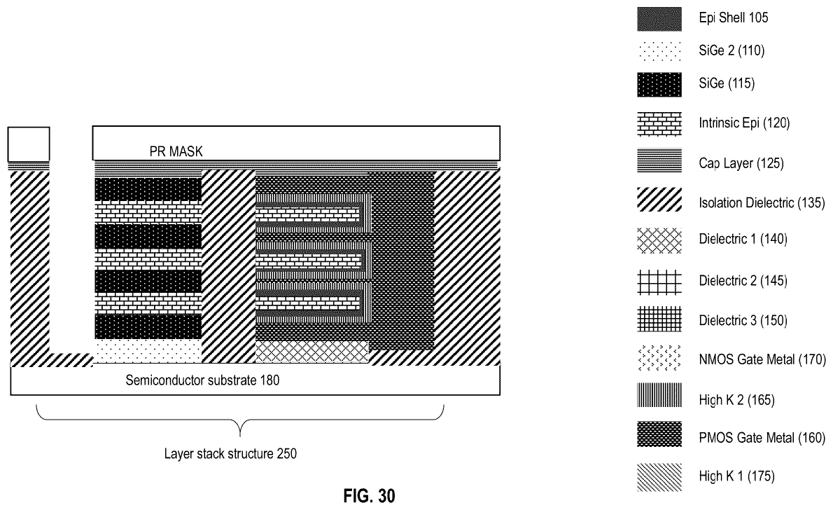

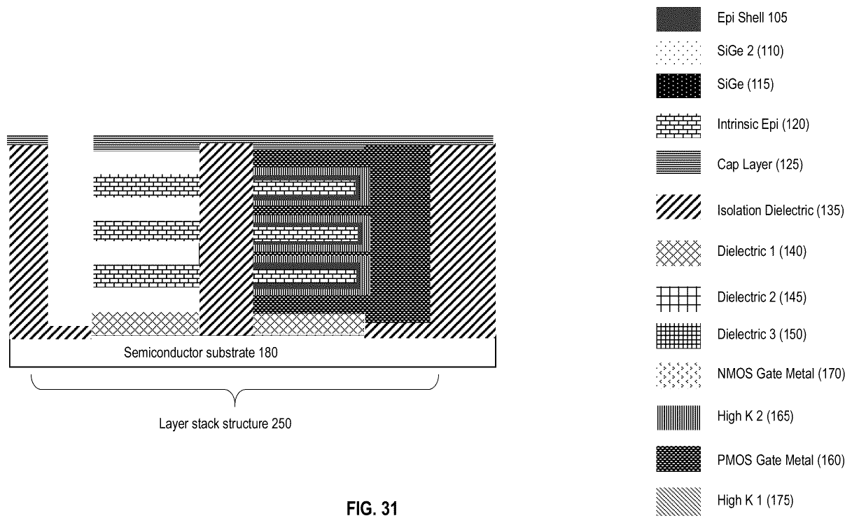

FIGS. 30-32 illustrate cross-sectional views of the layer stack structure 250 in which the steps same as or similar to those implemented with respect to the right side of the layer stack structure 250 discussed in FIGS. 25-29 can be implemented with respect to the left side of the layer stack structure 250. In FIG. 30, a PR mask can be used to downward etch the channel to expose the left portion of the SiGe 110 layer and open up the nanosheet stack 240, using the steps similar to those discussed earlier in connection with FIG. 25. In FIG. 31, SiGe 110 layer can be removed using the steps similar to those described earlier in connection with FIG. 26.

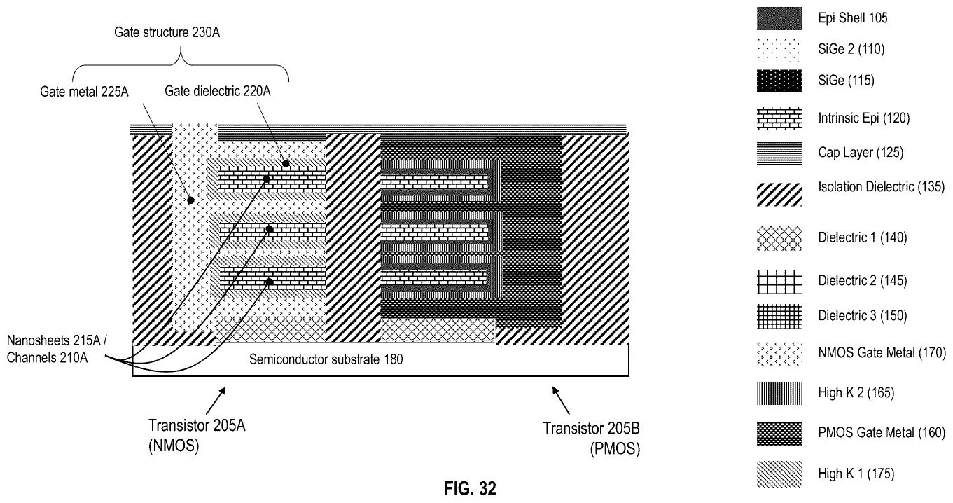

In FIG. 32, gate structure 230A can be formed using the steps and techniques similar to those discussed in connection with FIG. 29. A gate dielectric 220A can be formed with a deposition, forming or coating of a layer of high-k 1 175 on top of the nanosheets 215A to form channels 210A. This can be followed by a deposition of gate metal 225A, which can be implemented with NMOS gate metal 170. NMOS gate metal 170 can fill the voids and the gaps left in the prior steps, completing the gate structure 230A. At this point, transistors 205A and 205B can be complete.

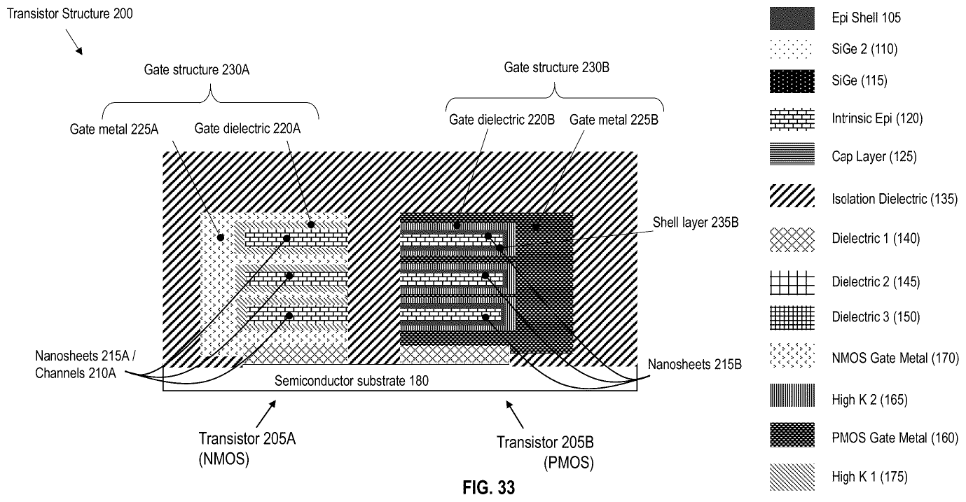

FIG. 33 illustrates the completed transistor structure 200 including an NMOS transistor 205A and a PMOS transistor 205B. NMOS transistor 205A can include nanosheets 215A and channels 210A, each one of which is surrounded by gate structure 230A. Likewise, PMOS transistor 205B can include nanosheets 215B and channels 210B, each one of which is surrounded by gate structure 230B. Transistor structure 200 in FIG. 33 can be similar to the transistor structure 200 in FIG. 21, except that the structure 200 in FIG. 21 includes gate structures 230 in the middle or central portion of the transistor structure (e.g., in between the transistors 205), while in FIG. 33 the gate structures 230 are on the outer portions of the transistor structure 200.

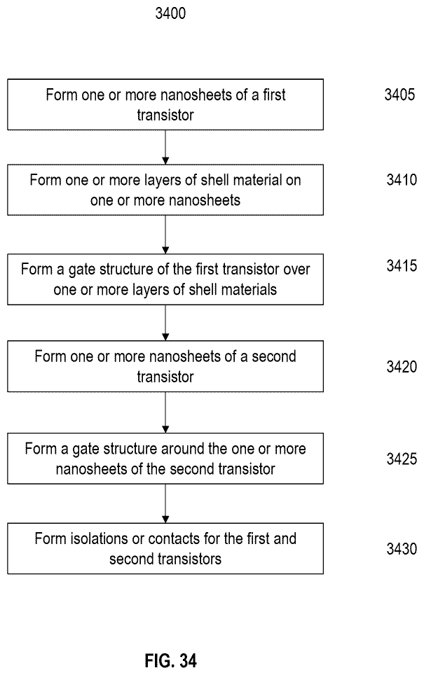

Referring now to FIG. 34, illustrated is a flow diagram of an example method 3400 for fabricating side-by-side transistor structures using any combination of fabrication techniques and steps described in FIGS. 1-33. The method 3400 can include steps 3405-3430. At step 3405, the method forms one or more nanosheets of a first transistor. At step 3410, the method forms one or more layers of shell material on one or more nanosheets. At step 3415, the method forms a gate structure of the first transistor over one or more layer of shell material. At step 3420, the method forms one or more nanosheets of a second transistor. At step 3425, the method forms a gate structure around one or more nanosheets of the second transistor. At step 3430, the method forms isolations or contacts for the first and second transistors.

At step 3405, the method forms one or more nanosheets of a first transistor. The first transistor can be a transistor of a plurality of transistors in a transistor structure. The first transistor can be PMOS transistor. The first transistor can be an NMOS transistor. The method can form a nanosheet based on a layer of a nanosheet material. The layer of the nanosheet material can be a first layer of nanosheet material. The first layer of nanosheet material can be a layer of the nanosheet material that is at a top nanosheet material layer (e.g., disposed above other nanosheet materials) in the stack of materials for forming a transistor structure. The layer of nanosheet material can include a horizontally oriented layer of material deposited on one or more layers on a substrate. The nanosheet material can include a deposited layer of material or an epitaxially grown material. The nanosheet material can include epitaxially grown dielectric or epitaxially grown semiconductor. The nanosheet material can include epitaxially grown intrinsic silicon material, germanium material, or a silicon germanium material.

The method can include forming a second nanosheet based on a second layer of the nanosheet material. The second layer can be oriented horizontally and disposed beneath the layer of the nanosheet material that is also oriented horizontally. The method can include forming a third nanosheet formed based on a third layer of the nanosheet material. The third layer can be oriented horizontally and disposed beneath the second layer of the nanosheet material. The first, the second and the third layers can be spaced apart from each other. The method can include forming the nanosheet material to include an epitaxially grown silicon material.

At step 3410, the method forms one or more layers of shell material on one or more nanosheets, such as the nanosheets of the first transistor. The layer of shell material can be formed by epitaxially growing a shell material on a nanosheet, such as the first nanosheet of the first transistor. The layer of shell material can be formed by depositing or forming a layer of shell material on a nanosheet. The method can include forming a layer of a shell material at least partly surrounding the nanosheet to form a channel of a transistor, such as the first channel of the first transistor. The shell material can include material properties that improve performance of the first transistor, such as change, increase or decrease the speed of the transistor charge or discharge. The shell material can include a charge carrier mobility that is greater than a charge carrier mobility of the nanosheet material. The shell material can include a charge carrier mobility that is less than the charge carrier mobility of the nanosheet material. The method can include forming a second layer of the shell material at least partly surrounding the second nanosheet to form a second channel of the transistor that is a p-type metal oxide semiconductor (PMOS) transistor. The method can include forming a third layer of the shell material at least partly surrounding the third nanosheet to form a third channel of the PMOS transistor.

The method can include forming a layer of a second shell material disposed between the layer of the shell material (e.g., first layer of shell material deposited on the nanosheet) and the gate dielectric. The second shell material can at least partly surround the layer of the shell material. The second shell material can be different than the shell material and include a charge carrier mobility that is greater than the charge carrier mobility of the nanosheet material. The shell material and the second shell material can both include charge carrier mobility that is larger or greater than that of the nanosheet material. The second shell material can include the charge carrier mobility that is greater than the charge carrier mobility of the first shell material directly deposited on the nanosheet. The second shell material can include the charge carrier mobility that is less than the charge carrier mobility of the first shell material directly deposited on the nanosheet.

The method can include forming the shell material to include one of a Ge or a SiGe alloy. The method can include forming the second shell material to include a remaining one of the Ge or a SiGe alloy. The method can include forming the shell material to include a first SiGe alloy having a first molar ratio of silicon and germanium. The method can include forming the second shell material to include a second SiGe alloy having a second molar ratio of silicon and germanium.

At step 3415, the method forms a gate structure of the first transistor over one or more layer of shell material. The gate structure can include a gate electrode surrounding the nanosheets or channels of the first transistor. The method can include forming a layer of a gate dielectric of a gate structure of the transistor over the layer of the shell material. The method can include forming a gate metal of the gate structure over the layer of gate dielectric. The gate structure can at least partly surrounds the channel. The gate structure can surround the channel from multiple sides, including from above (e.g., top side of the nanosheet), below (e.g., bottom side of the nanosheet) and from a side of the nanosheet that borders with or is adjacent to the top and the bottom sides. The method can include forming the gate structure of the PMOS transistor. The gate structure can at least partly surrounding the second channel and at least partly surrounding the third channel. The gate structure can include the gate dielectric disposed between the gate metal and the second layer of the shell material. The gate structure can be disposed between the gate metal and the third layer of the shell material.

At step 3420, the method forms one or more nanosheets of a second transistor. The second transistor can be an NMOS transistor. The second transistor can be a PMOS transistor. The second transistor can be a transistor formed beside the first transistor. The second transistor can be a transistor formed in the same transistor structure as the first transistor. The second transistor can share the same layers of materials as the first transistor. The second transistor can share the same layers of material forming the nanosheets of the second transistor as the layers that are used to form nanosheets of the first transistor.

The method can include forming a fourth nanosheet for a fourth channel of an n-type metal oxide semiconductor (NMOS) transistor disposed beside the PMOS transistor. The fourth nanosheet can be formed based on the layer of the nanosheet material. The method can include forming a fifth nanosheet for a fifth channel of the NMOS transistor. The fifth nanosheet can be formed based on the second layer of the nanosheet material. The method can include forming a sixth nanosheet for a sixth channel of the NMOS transistor. The sixth nanosheet can be formed based on the third layer of the nanosheet material. The method can include forming the nanosheet material to include an epitaxially grown silicon material. The method can include forming the shell material to include one of a germanium (Ge) material or a silicon germanium (SiGe) alloy material.

At step 3425, the method forms a gate structure around one or more nanosheets of the second transistor. The gate structure can include a gate electrode formed around or surrounding the channels formed using the nanosheets of the second transistor. The method can include forming a second gate structure of the second transistor. The second gate structure can at least partly surround each of the fourth channel, the fifth channel, and the sixth channel. For instance, the second gate structure can surround each of the fourth, the fifth and the sixth channel from at least three sides, such as from the top, bottom and a side that is adjacent to both top and bottom nanosheet or channel surfaces. The second gate structure can include a second gate dielectric disposed between a second gate metal of the second gate structure and the fourth nanosheet. The second gate structure can include a second gate dielectric disposed between the second gate metal and the fifth nanosheet. The second gate structure can include a second gate dielectric disposed between the second gate metal and the sixth nanosheet. The second gate metal can be deposited or formed on top of the second gate dielectric and can surround each of the channels or nanosheets of the second transistor.

At step 3430, the method forms isolations or contacts for the first and second transistors. The first and the second transistors can include gate structures that are formed on the interior part or the middle portion of the layer stack structure and can be electrically insulated or separated by a layer of dielectric material disposed in a trench between the gate structures of the two transistors. The first and the second transistors can have their gate structures electrically shorted by a layer of metal that can be deposited into the trench between the gate structures of the two transistors. The first transistor or the second transistor can include edge isolations at the outer edges of the nanosheets forming the channels. The edge isolations can be formed using indent etches of the nanosheet material, followed by dielectric filling of the indent etched areas of the nanosheet material layers.

The method can include forming an isolation trench oriented vertically and disposed between the gate structure of the PMOS transistor and the second gate structure of the NMOS transistor. The isolation trench can electrically isolate the gate structure and the second gate structure. The method can include forming a metal trench oriented vertically and disposed between the gate structure of the PMOS transistor and the second gate structure of the NMOS transistor. The metal trench electrically coupling the gate structure and the second gate structure to form an inverter.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A structure comprising a transistor, the transistor comprising:
a nanosheet formed on a layer of a nanosheet material;
a layer of a shell material at least partly surrounding the nanosheet to form a channel; and
a gate structure at least partly surrounding the channel, the gate structure comprising a gate dielectric disposed between the layer of the shell material and a gate metal of the gate structure, wherein the shell material includes a charge carrier mobility that is greater than a charge carrier mobility of the nanosheet material.

2. The structure of claim 1, wherein the transistor is a p-type metal oxide semiconductor (PMOS) transistor and the layer of a nanosheet material is oriented horizontally, the PMOS transistor comprising:
a second nanosheet formed based on a second layer of the nanosheet material, the second layer oriented horizontally and disposed beneath the layer of the nanosheet material;
a third nanosheet formed based on a third layer of the nanosheet material, the third layer oriented horizontally and disposed beneath the second layer of the nanosheet material;
a second layer of the shell material at least partly surrounding the second nanosheet to form a second channel;
a third layer of the shell material at least partly surrounding the third nanosheet to form a third channel; and
the gate structure at least partly surrounding the second channel and at least partly surrounding the third channel, the gate dielectric disposed between the gate metal and the second layer of the shell material and between the gate metal and the third layer of the shell material.

3. The structure of claim 2, wherein the PMOS transistor is disposed beside an n-type metal oxide semiconductor (NMOS) transistor, the NMOS transistor comprising:
a fourth nanosheet to form a fourth channel, the fourth nanosheet formed based on the layer of the nanosheet material;
a fifth nanosheet to form a fifth channel, the fifth nanosheet formed based on the second layer of the nanosheet material;
a sixth nanosheet to form a sixth channel, the sixth nanosheet formed based on the third layer of the nanosheet material; and
a second gate structure at least partly surrounding each of the fourth channel, the fifth channel, and the sixth channel, the second gate structure comprising a second gate dielectric disposed between a second gate metal of the second gate structure and the fourth nanosheet between the second gate metal and the fifth nanosheet and between the second gate metal and the sixth nanosheet.

4. The structure of claim 3, comprising:
an isolation trench oriented vertically and disposed between the gate structure of the PMOS transistor and the second gate structure of the NMOS transistor, the isolation trench electrically isolating the gate structure and the second gate structure.

5. The structure of claim 3, comprising:
a metal trench oriented vertically and disposed between the gate structure of the PMOS transistor and the second gate structure of the NMOS transistor, the metal trench electrically coupling the gate structure and the second gate structure to form an inverter.

6. The structure of claim 1, wherein the nanosheet material includes an epitaxially grown silicon material.

7. The structure of claim 6, wherein the shell material includes one of a germanium (Ge) material or a silicon germanium (SiGe) alloy material.

8. The structure of claim 1, comprising:
a layer of a second shell material disposed between the layer of the shell material and the gate dielectric and at least partly surrounding the layer of the shell material, the second shell material different than the shell material, the second shell material including a charge carrier mobility that is greater than the charge carrier mobility of the nanosheet material.

9. The structure of claim 8, wherein the shell material is one of a Ge or a SiGe alloy and the second shell material is a remaining one of the Ge or a SiGe alloy.

10. The structure of claim 8, wherein the shell material includes a first SiGe alloy having a first molar ratio of silicon and germanium and the second shell material includes a second SiGe alloy having a second molar ratio of silicon and germanium.

11. A method comprising:
forming a nanosheet based on a layer of a nanosheet material;
forming a layer of a shell material at least partly surrounding the nanosheet to form a channel of a transistor, wherein the shell material includes a charge carrier mobility that is greater than a charge carrier mobility of the nanosheet material;
forming a layer of a gate dielectric of a gate structure of the transistor over the layer of the shell material; and
forming a gate metal of the gate structure over the layer of gate dielectric, wherein the gate structure at least partly surrounds the channel.

12. The method of claim 11, comprising:
forming a second nanosheet based on a second layer of the nanosheet material, the second layer oriented horizontally and disposed beneath the layer of the nanosheet material that is oriented horizontally;
forming a third nanosheet formed based on a third layer of the nanosheet material, the third layer oriented horizontally and disposed beneath the second layer of the nanosheet material;
forming a second layer of the shell material at least partly surrounding the second nanosheet to form a second channel of the transistor that is a p-type metal oxide semiconductor (PMOS) transistor;
forming a third layer of the shell material at least partly surrounding the third nanosheet to form a third channel of the PMOS transistor; and
forming the gate structure of the PMOS transistor, the gate structure at least partly surrounding the second channel and at least partly surrounding the third channel, the gate structure including the gate dielectric disposed between the gate metal and the second layer of the shell material and disposed between the gate metal and the third layer of the shell material.

13. The method of claim 12, comprising:
forming a fourth nanosheet for a fourth channel of an n-type metal oxide semiconductor (NMOS) transistor disposed beside the PMOS transistor, the fourth nanosheet formed based on the layer of the nanosheet material;
forming a fifth nanosheet for a fifth channel of the NMOS transistor, the fifth nanosheet formed based on the second layer of the nanosheet material;
forming a sixth nanosheet for a sixth channel of the NMOS transistor, the sixth nanosheet formed based on the third layer of the nanosheet material; and
forming a second gate structure at least partly surrounding each of the fourth channel, the fifth channel, and the sixth channel, the second gate structure comprising a second gate dielectric disposed between a second gate metal of the second gate structure and the fourth nanosheet between the second gate metal and the fifth nanosheet and between the second gate metal and the sixth nanosheet.

14. The method of claim 13, comprising:
forming an isolation trench oriented vertically and disposed between the gate structure of the PMOS transistor and the second gate structure of the NMOS transistor, the isolation trench electrically isolating the gate structure and the second gate structure.

15. The method of claim 13, comprising:
forming a metal trench oriented vertically and disposed between the gate structure of the PMOS transistor and the second gate structure of the NMOS transistor, the metal trench electrically coupling the gate structure and the second gate structure to form an inverter.

16. The method of claim 11, comprising forming the nanosheet material to include an epitaxially grown silicon material.

17. The method of claim 16, comprising forming the shell material to include one of a germanium (Ge) material or a silicon germanium (SiGe) alloy material.

18. The method of claim 11, comprising:
forming a layer of a second shell material disposed between the layer of the shell material and the gate dielectric, the second shell material at least partly surrounding the layer of the shell material, the second shell material different than the shell material and including a charge carrier mobility that is greater than the charge carrier mobility of the nanosheet material.

19. The method of claim 18, comprising:
forming the shell material to include one of a Ge or a SiGe alloy; and
forming the second shell material to include a remaining one of the Ge or a SiGe alloy.

20. The method of claim 18, comprising:
forming the shell material to include a first SiGe alloy having a first molar ratio of silicon and germanium; and
forming the second shell material to include a second SiGe alloy having a second molar ratio of silicon and germanium.
